(19) United States
(12) Patent Application Publication
(10) Pub. No.: US 2026/0280233 A1
(43) Pub. Date: Sep. 17, 2026

(54) LASER WAFER WITH AN ARRAY OF ACTIVE REGIONS HAVING DIFFERENT REFLECTIVITIES CREATED USING A FOCUSED ION BEAM TOOL

(71) Applicant: Microchip Technology Inc., Chandler, AZ (US)

(72) Inventors: Steve Nagel, Chandler, AZ (US); Bomy Chen, Newark, CA (US)

(73) Assignee: Microchip Technology Inc., Chandler, AZ (US)

(21) Appl. No.: 19/269,948

(22) Filed: Jul. 15, 2025

Related U.S. Application Data
(60) Provisional application No. 63/771,335, filed on Mar. 13, 2025.

(51) Int. Cl. H01S 5/183; H01S 5/02; H01S 5/125; H01S 5/343

(52) U.S. Cl. CPC H01S 5/18361; H01S 5/0206; H01S 5/125; H01S 5/343

(57) ABSTRACT

A system and method for creating a laser wafer with an array of active regions having different reflectivities created using a focused ion beam tool are disclosed. The semiconductor wafer may include a substrate, a first distributed Bragg reflector (DBR) formed on the substrate, a first active region formed on the first DBR, a second active region formed on the first DBR, a second DBR formed on the first and second active regions, and a contact layer formed on the second DBR. The first active region may include a base material and a first concentration of a doped material introduced by a focused ion beam tool to reflect at a first wavelength. The second active region may include the base material and a second concentration of the doped material introduced by the focused ion beam tool to reflect at a second wavelength.

### PRIORITY

This application claims priority to U.S. Provisional Patent Application No. 63/771,335 filed March 13, 2025, the contents of which are hereby incorporated in their entirety.

### TECHNICAL FIELD

The present disclosure relates to lasers, and in particular, to a system and method for creating a laser wafer with an array of active regions having different reflectivities created using a focused ion beam tool.

### BACKGROUND

Edge-emitting lasers (EELs) and vertical cavity surface emitting lasers (VCSELs) are two different types of diode lasers. In an EEL, light is emitted from the edge of a substrate. A solid-state laser is grown within a semiconductor wafer, with the optical cavity parallel to the surface of the wafer. The wafer is cleaved at both ends and coated with a mirror to create the laser. In a VCSEL, the light is emitted perpendicular to the mounting surface, as opposed to an EEL, which emits light parallel to the surface. In a VCSEL, epitaxial layers are deposited on top of the wafer, with an optical cavity between them. Both EELs and VCSELs are used in telecommunications applications, such as for fiber optic transmission.

Bulk single crystal wafers for EELs and VCSELs are grown using high precision processes and are cut into discs and polished to obtain high quality wafer surfaces as the starting substrate material for growing one or more epitaxial layers to construct EELs and VCSELs. Processes such as metal-organic chemical vapor deposition (MOCVD) and/or molecular beam epitaxy (MBE) may be used to grow epitaxial layers with precise composition and thickness control. The epitaxial layers are used to construct reflectors including distributed Bragg reflectors (DBR) and dielectric mirrors as well as the active gain region to form a laser cavity, aperture layer(s) for current confinement, etch stop layer and electrical contact.

The active gain region may be formed of a variety of materials, such as crystals, typically doped with rare-earth ions (e.g., neodymium, ytterbium, or erbium) or transition metal ions (titanium or chromium), such as yttrium aluminum garnet (Y3Al5O12), yttrium orthovanadate (YVO4), or sapphire (Al2O3); glasses (e.g., silicate or phosphate glasses) doped with laser-active ions; gases (e.g., mixtures of helium and neon (HeNe), nitrogen, argon, krypton, carbon monoxide, carbon dioxide, or metal vapors); semiconductors (e.g., gallium arsenide (GaAs), indium gallium arsenide (InGaAs), or gallium nitride (GaN)); or liquids, in the form of dye solutions as used in dye lasers.

### SUMMARY OF THE INVENTION

Aspects provide systems and methods for creating a laser wafer with an array of active regions having different reflectivities created using a focused ion beam tool. Examples of the present disclosure may include a semiconductor wafer. The semiconductor wafer may include a substrate. The semiconductor wafer may also include a first distributed Bragg reflector (DBR) formed on the substrate. The semiconductor wafer may additionally include a first active region formed on the first DBR. The first active region may include a base material and a first concentration of a doped material introduced by a focused ion beam tool to reflect at a first wavelength. The semiconductor wafer may include a second active region formed on the first DBR. The second active region may include the base material and a second concentration of the doped material introduced by the focused ion beam tool to reflect at a second wavelength. The first concentration and the second concentration may be different and the first wavelength and the second wavelength may be different. The semiconductor wafer may also include a second DBR formed on the first and second active regions. The semiconductor wafer may further include a contact layer formed on the second DBR.

In combination with any of the above examples, the base material may be a compound including gallium arsenide.

In combination with any of the above examples, the doped material may be a dilute nitride.

In combination with any of the above examples, the first concentration and the second concentration may be less than five percent.

In combination with any of the above examples, the semiconductor wafer may be configured for use in a laser emitting light at the first wavelength and the second wavelength.

In combination with any of the above examples, the laser may be a vertical cavity surface emitting laser (VCSEL) or an edge emitting laser (EEL).

In combination with any of the above examples, the doped material may be applied to the first active region and the second active region using focused ion beam lithography.

Alone or in combination with any of the above examples, examples of the present disclosure may include a method. The method may include forming a first distributed Bragg reflector (DBR) on a substrate of a semiconductor wafer. The method may also include creating a first active region and a second active region on the first DBR. The first active region and the second active region may include a base material. The method may additionally include introducing, using a focused ion beam tool, a first concentration of a doped material to the first active region, the first concentration of the doped material to reflect at a first wavelength. The method may include introducing, using the focused ion beam tool, a second concentration of the doped material to the second active region. The second concentration of the doped material may be to reflect at a second wavelength. The first concentration and the second concentration may be different and the first wavelength and the second wavelength may be different. The method may also include forming a second DBR on the first active region and the second active region. The method may further include adding a contact layer on the second DBR.

In combination with any of the above examples, the base material may be a compound including gallium arsenide.

In combination with any of the above examples, the doped material may be a dilute nitride.

In combination with any of the above examples, the first concentration and the second concentration may be less than five percent.

In combination with any of the above examples, the semiconductor wafer may be configured for use in a laser emitting light at the first wavelength and the second wavelength.

In combination with any of the above examples, the laser may be a vertical cavity surface emitting laser (VCSEL) or an edge emitting laser (EEL).

In combination with any of the above examples, the method may include applying the doped material to the first active region and the second active region using focused ion beam lithography.

Alone or in combination with any of the above examples, examples of the present disclosure may include a semiconductor wafer. The semiconductor wafer may be created by a process. The process may include forming a first distributed Bragg reflector (DBR) on a substrate of a semiconductor wafer. The process may also include creating a first active region and a second active region on the first DBR. The first active region and the second active region may include a base material. The process may additionally include introducing, using a focused ion beam tool, a first concentration of a doped material to the first active region, the first concentration of the doped material to reflect at a first wavelength. The process may include introducing, using the focused ion beam tool, a second concentration of the doped material to the second active region. The second concentration of the doped material may be to reflect at a second wavelength. The first concentration and the second concentration may be different and the first wavelength and the second wavelength may be different. The process may also include forming a second DBR on the first active region and the second active region. The process may further include adding a contact layer on the second DBR.

In combination with any of the above examples, the base material may be a compound including gallium arsenide.

In combination with any of the above examples, the doped material may be a dilute nitride.

In combination with any of the above examples, the first concentration and the second concentration may be less than five percent.

In combination with any of the above examples, the semiconductor wafer may be configured for use in a laser emitting light at the first wavelength and the second wavelength, The laser may be a vertical cavity surface emitting laser (VCSEL) or an edge emitting laser (EEL).

In combination with any of the above examples, the doped material may be applied to the first active region and the second active region using focused ion beam lithography.

### BRIEF DESCRIPTION OF THE DRAWINGS

The figures illustrate examples of systems and methods for creating a laser wafer with an array of active regions having different reflectivities created using a focused ion beam tool.

FIG. 1 illustrates a perspective view of a cross section of a portion of a laser wafer (e.g., a wafer used in a vertical cavity surface emitting laser (VCSEL)), according to examples of the present disclosure;

FIG. 2 illustrates different substrates used for the active region and the wavelengths of light produced by lasers using the active region, according to examples of the present disclosure;

FIG. 3 illustrates a cross-sectional view of a wafer containing an array of active regions having different reflectivities for use in a laser, according to examples of the present disclosure;

FIG. 4 illustrates a top view of a wafer containing an array of active regions having different reflectivities for use in a laser, according to examples of the present disclosure;

FIG. 5 illustrates a tool for manufacturing a wafer containing an array of active regions having different reflectivities for use in a laser, according to examples of the present disclosure; and

FIG. 6 illustrates a method for manufacturing a wafer containing an array of active regions having different reflectivities for use in a laser, according to examples of the present disclosure.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect of the disclosure, systems and methods for creating a laser wafer with an array of active regions having different reflectivities created using a focused ion beam tool are provided. Faster data transmission speeds used for telecommunications are driving innovation in fiber optic communications and the ability to have a single array of lasers emitting light at multiple wavelengths may simplify and reduce the form factor for lasers used for fiber optic communications, as well as other applications. The array of lasers may be created by using a monolithic laser wafer having an array of active regions to allow the array of lasers to emit at different wavelengths. The multiple active regions may be created by doping the active regions using dilute nitride gallium arsenide (GaAs). The dilute GaAs may be applied using nitrogen gas ion field source in a focused ion beam (FIB) lithography tool. While FIB tools are typically used in a physical analysis environment, FIB tools may be added as a part of the process equipment to create a laser wafer with an array of active regions having different reflectivities to be used in a laser array. Using an FIB tool in conjunction with the process equipment may simplify the overall system cost, reduce the bill of materials, and reduce the system form factor when creating the laser wafer. The array of lasers may be useful when emitting different wavelengths of light simultaneously within a fiber optical cable. Additionally, the array of lasers may be useful for applications using wavelength division multiplexing.

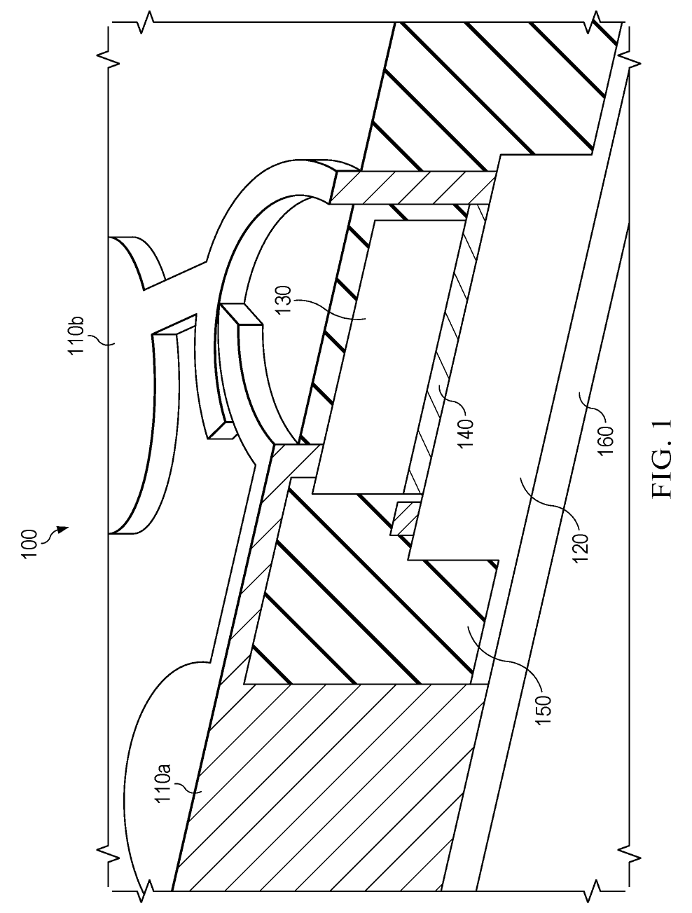

FIG. 1 illustrates a perspective view of a cross section of a portion of a laser wafer (e.g., a wafer used in a vertical cavity surface emitting laser (VCSEL)), according to examples of the present disclosure. Wafer 100 may include contacts 110, n-type distributed Bragg reflector (DBR) 120, p-type DBR 130, active region 140, and passivation layer 150.

Contacts 110 may provide N-contact and P-contact connections with an electrical pathway for current to flow in wafer 100. Contacts 110 may be made of any suitable conductive material, such as, but not limited to, gold, titanium, platinum, aluminum, nickel, or any combination thereof. In some examples, contacts 110 may be a contact layer on the top of the other layers (e.g., n-type distributed Bragg reflector (DBR) 120, p-type DBR 130, active region 140, and passivation layer 150) of wafer 100

N-type DBR 120 and p-type DBR 130 may act as mirrors to confine light within the optical cavity of wafer 100. N-type DBR 120 may be formed on substrate 160 (e.g., GaAs or indium phosphide (InP)). By confining light to the optical cavity of wafer 100, the light may be amplified by active region 140. N-type DBR 120 and p-type DBR 130 may be parallel to the surface of substrate 160. N-type DBR 120 and p-type DBR 130 may be formed of alternating layers of semiconductor materials with different refractive indices. Therefore, n-type DBR 120 and p-type DBR 130 may create a periodic structure to reflect light at specific wavelengths. N-type DBR 120 and p-type DBR 130 may be made of alloys of gallium arsenide (GaAs), aluminum gallium arsenide (AlₓGa₁₋ₓAs, or simply, AlGaAs), or any other suitable material or compound providing the electrical and thermal conductivity properties for a given application of the laser in which wafer 100 is incorporated.

Active region 140 may be responsible for generating laser light from wafer 100 using the process of optical gain. Active region 140 may be formed of multiple-quantum wells (MQWs) and contain one or more thin layers of semiconductor material. The thin layers of semiconductor may determine the wavelength of the light emitted. Specifically, active region 140 may be formed of a base material having a lattice length to correspond to the wavelength of light produced by the laser. Active region 140 may be formed of any suitable material or compound such as, but not limited to, GaAs/AlGaAs and indium gallium arsenide (InGaAs)/AlGaAs. In some examples, as described in more detail below, active region 140 may include a doped material introduced to the base material to change the wavelength at which a laser associated with active region 140 emits light.

Passivation layer 150 may serve as a planarization and passivation layer in wafer 100. For example, structures forming wafer 100 may have a rough and uneven surface. Passivation layer 150 may be applied to create a smooth and planar surface. Passivation layer 150 may then provide a flat surface for providing contact and bonding of other components to wafer 100. Additionally, passivation layer 150 may serve as a protective barrier to prevent unwanted oxidation of the internal structures of wafer 100. By protecting wafer 100 from exposure to the environment and suppressing surface defects, passivation layer 150 may increase the reliability of the laser in which wafer 100 is incorporated.

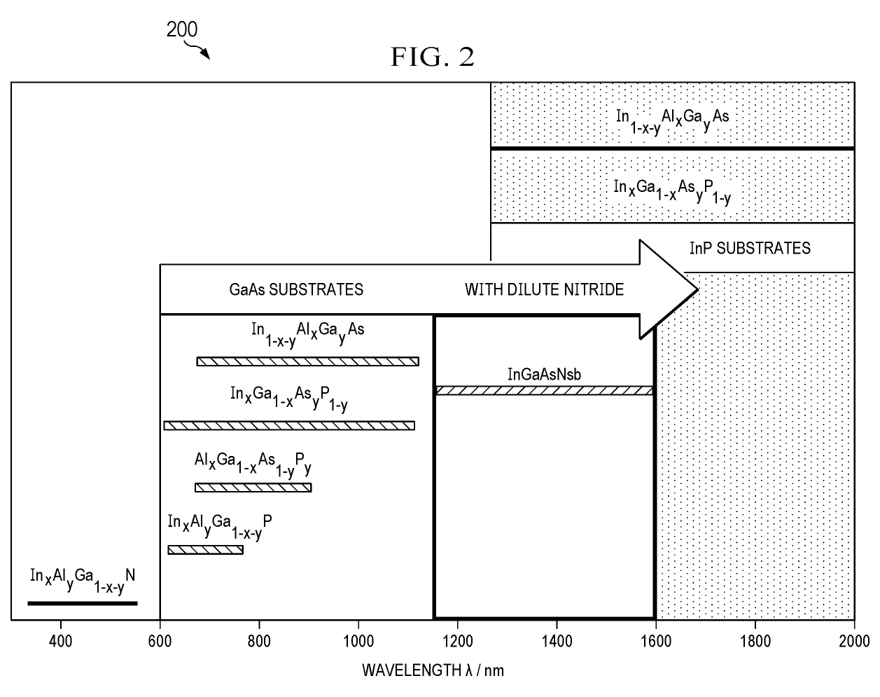

For example, FIG. 2 illustrates different substrates used for the active region and the wavelengths of light produced by lasers using the active region, according to examples of the present disclosure. As illustrated in FIG. 2, an active region formed of InₓAl_{y}Ga_{1-x-y}N may produce light at approximately 350 to approximately 550 nanometers (nm) while an active region formed of In_{1-x-y}AlₓGa_{y}As may produce light at approximately 1300 to approximately 2000 nm. As illustrated in FIG. 2, the addition of dilute nitrogen to an active region formed of a GaAs base may be increase the wavelength of the light produced by a laser using the active region. Additionally, the higher the concentration of dilute nitrogen added to the active region, the larger the wavelength of the light produced by the laser using the active region.

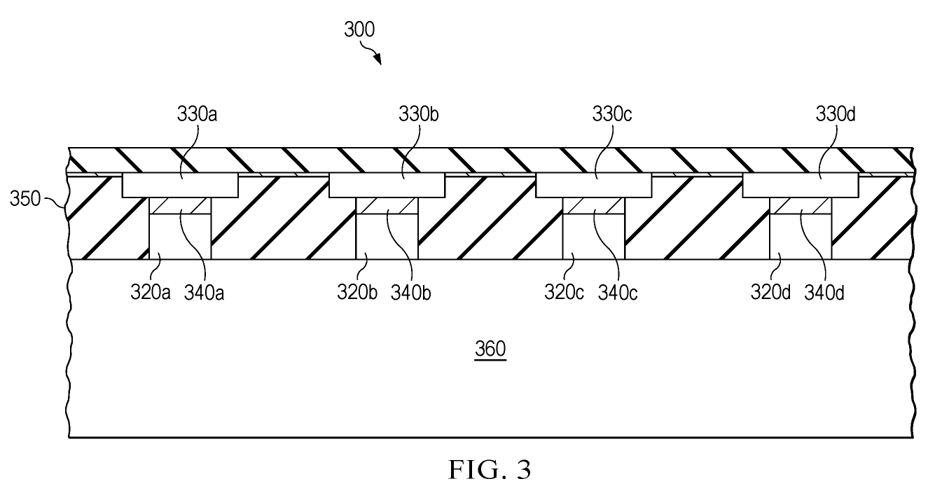

Wafer 100 may include multiple active regions for multiple lasers. FIG. 3 illustrates a cross-sectional view of a wafer containing an array of active regions having different reflectivities for use in a laser, according to examples of the present disclosure. Wafer 300 may include active regions 340a through 340d. Wafer 300 may be similar to wafer 100, shown in FIG. 1, and include n-type DBRs 320a through 320d, p-type DBRs 330a through 330d, active regions 340a through 340d, and passivation layer 350. N-type DBRs 320a through 320d, p-type DBRs 330a through 330d, active regions 340a through 340d, and passivation layer 350 may be similar to n-type DBR 120, p-type DBR 130, active region 140, and passivation layer 150, respectively, shown in FIG. 1.

Active regions 340a through 340d may be formed of materials having a different lattice length such that the laser associated with the given active region produces light at a different wavelength. For example, as explained with reference to FIG. 2, incorporating nitrogen (e.g., dilute nitride) into a GaAs active region may alter the crystalline structure and increase the emission wavelength of the laser associated with the active region. Therefore, active regions 340a, 340b, 340c, and 340d may be doped with a different concentrations of dilute nitride such that active regions 340a, 340b, 340c, and 340d have different crystalline structure and lasers associated with active regions 340a, 340b, 340c, and 340d emit light at different wavelengths. As a specific example, active region 340a may not be doped with dilute nitride (e.g., the dilute nitrogen concentration of active region 340a is zero) and active regions 340b through 340d may be doped with increasing amounts of dilute nitride (e.g., the dilute nitrogen concentration of active region 340b is approximately one percent, the dilute nitrogen concentration of active region 340c is approximately three percent, and the dilute nitrogen concentration of active region 340d is approximately five percent).

In addition, or as an alternative, to using dilute nitrogen to create different lattice lengths for active regions 340a, 340b, 340c, and 340d, other elements may be used to create the different lattice lengths, such as, but not limited to, gallium (Ga) or antimony (Sb).

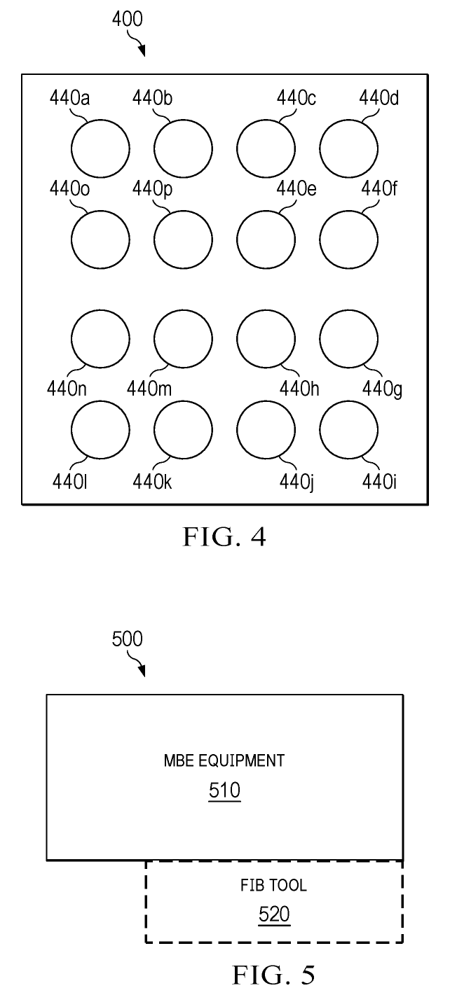

FIG. 4 illustrates a top view of a wafer containing an array of active regions having different reflectivities for use in a laser, according to examples of the present disclosure. Wafer 400 may include active regions 440a through 440p. Wafer 400 may be similar to wafer 100 and wafer 300, shown in FIGS. 1 and 3, respectively, and active regions 440a through 440p may be similar to active region 140 and active regions 340a through 340d shown in FIGS. 1 and 3, respectively.

Active regions 440a through 440p may be formed of materials having a different lattice length such that a first laser associated with a first active region 440 produces light at a first wavelength and a second laser associated with a second active region 440 produces light at a second wavelength. For example, active region 440a may be doped with a concentration of dilute nitrogen of approximately one percent and active region 440b may be doped with a concentration of dilute nitrogen of approximately two percent. Therefore, the laser associated with active region 440a may produce light at a first wavelength and the laser associated with active region 440b may produce light at a second wavelength. Because the concentrations of dilute nitrogen in active regions 440a and 440b are different, the first wavelength and the second wavelength are different.

Wafer 400 may allow for light to be emitted a wide variety of wavelengths produced using a single wafer 400. For example, wafer 400 contains sixteen active regions 440a through 440p. Active regions 440a through 440p may be doped with sixteen different concentrations of dilute nitride resulting in light being emitted at sixteen different wavelengths. As another example, active regions 440a through 440p may be doped with less than sixteen different concentrations of dilute nitride, resulting in some active regions 440 emitting light at the same wavelength as other active regions 440.

Active regions 440a through 440p may be created by adding an element (e.g., dilute nitrogen) to active regions 440a through 440p such that the crystalline structure of active regions 440a through 440p is altered such that the lasers associated with active regions 440a through 440p emits light at different wavelengths. The element may be added at various points in process of manufacturing wafer 400. For example, the element may be added to active regions 440a through 440p during the molecular beam epitaxy (MBE) process. As another example, the element may be added by an ion implant into the base material of the active region (e.g., a nitrogen ion implant into the GaAs) followed by an annealing process. As an additional example, a photolithography pattern may be used and the element may be implanted in the active regions. As a further example, as described in more detail with respect to FIG. 5, a focused ion beam (FIB) tool with a field ion source (e.g., a nitrogen gas field ion source) may be used to dope active regions 440a through 440p with varying doses of the field ion source. Wafer 400 may then be used to produce light at multiple wavelengths by multiple lasers (e.g., a VCSEL, a VCSEL with a tunnel junction, a lateral tunnel junction laser, or EEL) using a single wafer 400.

FIG. 5 illustrates a tool for manufacturing a wafer containing an array of active regions having different reflectivities for use in a laser, according to examples of the present disclosure. Tool 500 may include MBE equipment 510 and FIB tool 520. FIB tool 520 may be added to MBE equipment 510 such that FIB tool 520 may perform the doping process to add the element to the active regions of the wafer without breaking the vacuum environment of MBE equipment 510 when manufacturing the wafer.

MBE equipment 510 may be used to grow a wafer, such as wafer 300 or wafer 400 shown in FIGS. 3 and 4, respectively. Within a vacuum chamber, heated effusion cells containing source materials (like metals or semiconductors) may emit beams of atoms or molecules. The beams may travel towards a heated substrate, where the beams may condense and be arranged into a crystalline structure. MBE equipment 510 may be monitored in real-time using techniques like reflection high-energy electron diffraction (RHEED), to control the film’s composition, thickness, and structure. By regulating the source material fluxes and substrate temperature, MBE may enable the creation of complex multilayer structures. MBE equipment 510 may be used to create the base structure (e.g., the GaAs layers) of one or more active regions on the wafer.

FIB tool 520 may be incorporated into the vacuum chamber containing MBE equipment 510. FIB tool 520 may operate by generating a finely focused beam of ions (e.g., dilute nitrogen ions) to perform focused ion beam lithography. FIB tool 520 may accelerate and direct the beam onto the substrate created by MBE equipment 510. FIB tool 520 may control the intensity and focus of the beam to achieve varying levels of material deposition to create active regions on the wafer having varying concentrations of the ions emitted by FIB tool 520 such that the lasers associated with the active regions produce light at different wavelengths. For example, FIB tool 520 may be used to dope the active regions on the wafer such that the wafer has a plurality of active regions having different concentrations of the element (e.g., dilute nitrogen) such that the active regions have different crystalline structures.

The wafer having an array of active regions disclosed above may be associated with an array of lasers and used to produce laser beams at different wavelengths. The resulting laser array may be used to perform wavelength-division multiplexing for longer distance or higher density fiber optic networks. For example, wavelength division multiplexing typically relies on individual lasers at a fixed wavelength for each channel. Using the systems and methods described above, single wafer could be used to create a laser array of individual lasers for each channel.

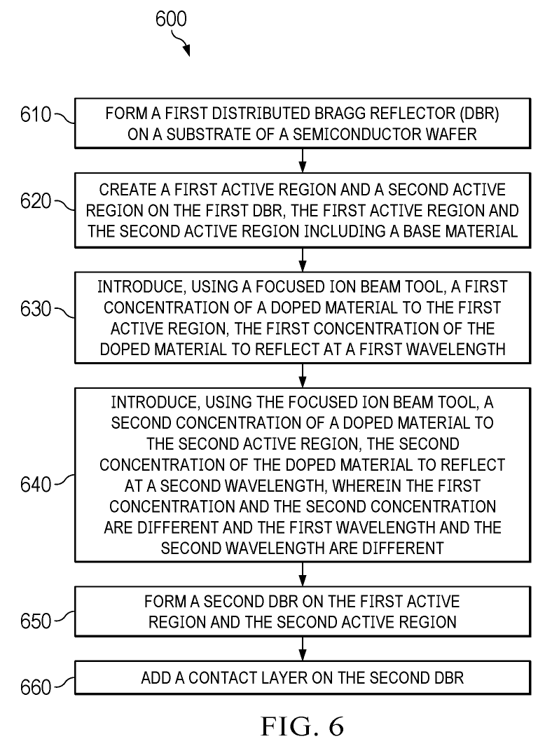

FIG. 6 illustrates a method for manufacturing a wafer containing an array of active regions having different reflectivities for use in a laser, according to examples of the present disclosure. Method 600 may be implemented using any suitable semiconductor manufacturing device designed to perform the functions disclosed herein or any other system operable to implement method 600. For example, method 600 may be performed by tool 500 shown in FIG. 5 including MBE equipment 510 and FIB tool 520. Although examples have been described above, other variations and examples may be made from this disclosure without departing from the spirit and scope of these disclosed examples.

Method 600 may begin at block 610 where a first DBR may be formed on a substrate of a semiconductor wafer. The first DBR may be an n-type DBR or a p-type DBR and may act as a mirror to confine light within the optical cavity of the semiconductor wafer. The first DBR may be parallel to the surface of the substrate and may be formed of alternating layers of semiconductor materials with different refractive indices, creating a periodic structure to reflect light at specific wavelengths. The first DBR may be made of alloys of gallium arsenide (GaAs), aluminum gallium arsenide (AlₓGa₁₋ₓAs, or simply, AlGaAs), or any other suitable material or compound providing the electrical and thermal conductivity properties for a given application of the laser in which the semiconductor wafer is incorporated.

At block 620, a first active region and a second active region may be created on the first DBR. The first active region and the second active region may include a base material. The first active region and the second active region may be adjacent to one another, such as active regions 340a and 340b shown in FIG. 3 or active regions 440a and 440 shown in FIG. 4. The first active region and the second active region may be responsible for generating laser light from the semiconductor wafer using the process of optical gain. The first active region and the second active region may be formed of multiple-quantum wells (MQWs) and contain one or more thin layers of semiconductor material. The thin layers of semiconductor may determine the wavelength of the light emitted. Specifically, the first active region and the second active region may be formed of a material having a lattice length to correspond to the wavelength of light produced by the laser. The base material used for first active region and the second active region may be any suitable material or compound such as, but not limited to, GaAs/AlGaAs and indium gallium arsenide (InGaAs)/AlGaAs.

At block 630, a first concentration of a doped material may be introduced to the first active region using a focused ion beam tool. The first concentration of the doped material may reflect at a first wavelength. The doped material may be an element such a nitrogen, gallium, or antimony that, when added to the material of the first active region, changes the crystalline structure of the first active region. The addition of the doped material may increase the wavelength of the light emitted by a laser associated with the first active region. For example, the higher the concentration of dilute nitrogen added to the first active region, the larger the wavelength of the light produced by the laser using the first active region. The first concentration of the doped material may be any suitable amount, for example, the first concentration may range from between approximately zero percent to approximately five percent.

At block 640, a second concentration of a doped material may be introduced to the second active region using a focused ion beam tool. The second concentration of the doped material may reflect at a second wavelength. The doped material may be an element such a nitrogen, gallium, or antimony that, when added to the material of the second active region, changes the crystalline structure of the second active region. The addition of the doped material may increase the wavelength of the light emitted by a laser associated with the second active region. For example, the higher the concentration of dilute nitrogen added to the second active region, the larger the wavelength of the light produced by the laser using the second active region. The second concentration of the doped material may be any suitable amount, for example, the second concentration may range from between approximately zero percent to approximately five percent. In some examples, the doped material introduced to the second active region may be different from the doped material introduced to the first active region. For example, dilute nitrogen may be introduced to the first active region and antimony may be introduced to the second active region.

The first concentration may be different from the second concentration. For example, where the doped material is dilute nitrogen, the first concentration and second concentration may be less than approximately five percent (e.g., the first concentration may be approximately one percent and the second concentration may be approximately three percent). The second wavelength may be different from the first wavelength. Therefore, a laser emitting light using the first active region may emit light at a different wavelength than a laser emitting light using the second active region. As such, the semiconductor wafer may be used to produce light at multiple wavelengths by multiple lasers (e.g., a VCSEL, a VCSEL with a tunnel junction, a lateral tunnel junction laser, or EEL) using a single semiconductor wafer.

The doped material may be introduced to the first active region and the second active region using a focused ion beam tool. For example, FIB tool 520 shown in FIG. 5 may be used to introduce the doped material. The doped material may be introduced to the first active region and the second active region without breaking the vacuum environment of the MBE equipment used to manufacture the semiconductor wafer. The focused ion beam tool may apply a first concentration of the doped material to the first active region and a second concentration of the doped material to the second active region by controlling the intensity and focus of the beam to achieve varying levels of material deposition to create active regions on the wafer having varying concentrations of the ions emitted by focused ion beam tool.

At block 650, a second DBR may be formed on the first active region and the second active region. The second DBR may be an n-type DBR or a p-type DBR and may act as a mirror to confine light within the optical cavity of the semiconductor wafer. The second DBR may be parallel to the surface of the substrate and may be formed of alternating layers of semiconductor materials with different refractive indices, creating a periodic structure to reflect light at specific wavelengths. The second DBR may be made of alloys of gallium arsenide (GaAs), aluminum gallium arsenide (AlₓGa₁₋ₓAs, or simply, AlGaAs), or any other suitable material or compound providing the electrical and thermal conductivity properties for a given application of the laser in which the semiconductor wafer is incorporated.

At block 660, a contact layer may be added to the second DBR. The contact layer may provide N-contact and P-contact connections with an electrical pathway for current to flow in a laser associated with the semiconductor wafer. The contacts may be made of any suitable conductive material, such as, but not limited to, gold, titanium, platinum, aluminum, nickel, or any combination thereof.

Although FIG. 6 discloses a particular number of operations related to method 600, method 600 may be executed with greater or fewer operations than those depicted in FIG. 6. In addition, although FIG. 6 discloses a certain order of operations to be taken with respect to method 600, the operations comprising method 600 may be completed in any suitable order.

Although examples have been described above, other variations and examples may be made from this disclosure without departing from the spirit and scope of these disclosed examples.

1. A semiconductor wafer, comprising:
a substrate;
a first distributed Bragg reflector (DBR) formed on the substrate;
a first active region formed on the first DBR, the first active region including a base material and a first concentration of a doped material introduced by a focused ion beam tool to reflect at a first wavelength;
a second active region formed on the first DBR, the second active region including the base material and a second concentration of the doped material introduced by the focused ion beam tool to reflect at a second wavelength, wherein the first concentration and the second concentration are different and the first wavelength and the second wavelength are different;
a second DBR formed on the first and second active regions; and
a contact layer formed on the second DBR.

2. The semiconductor wafer of claim 1, wherein the base material is a compound including gallium arsenide.

3. The semiconductor wafer of claim 1, wherein the doped material is a dilute nitride.

4. The semiconductor wafer of claim 1, wherein the first concentration and the second concentration are less than five percent.

5. The semiconductor wafer of claim 1, wherein the semiconductor wafer is configured for use in a laser emitting light at the first wavelength and the second wavelength.

6. The semiconductor wafer of claim 5, wherein the laser is a vertical cavity surface emitting laser (VCSEL) or an edge emitting laser (EEL).

7. The semiconductor wafer of claim 1, wherein the doped material is applied to the first active region and the second active region using focused ion beam lithography.

8. A method, comprising:
forming a first distributed Bragg reflector (DBR) on a substrate of a semiconductor wafer;
creating a first active region and a second active region on the first DBR, the first active region and the second active region including a base material;
introducing, using a focused ion beam tool, a first concentration of a doped material to the first active region, the first concentration of the doped material to reflect at a first wavelength;
introducing, using the focused ion beam tool, a second concentration of the doped material to the second active region, the second concentration of the doped material to reflect at a second wavelength, wherein the first concentration and the second concentration are different and the first wavelength and the second wavelength are different;
forming a second DBR on the first active region and the second active region; and
adding a contact layer on the second DBR.

9. The method of claim 8, wherein the base material is a compound including gallium arsenide.

10. The method of claim 8, wherein the doped material is a dilute nitride.

11. The method of claim 8, wherein the first concentration and the second concentration are less than five percent.

12. The method of claim 8, wherein the semiconductor wafer is configured for use in a laser emitting light at the first wavelength and the second wavelength.

13. The method of claim 12, wherein the laser is a vertical cavity surface emitting laser (VCSEL) or an edge emitting laser (EEL).

14. The method of claim 8, comprising applying the doped material to the first active region and the second active region using focused ion beam lithography.

15. A semiconductor wafer, created by a process comprising:
forming a first distributed Bragg reflector (DBR) on a substrate of a semiconductor wafer;
creating a first active region and a second active region on the first DBR, the first active region and the second active region including a base material;
introducing, using a focused ion beam tool, a first concentration of a doped material to the first active region, the first concentration of the doped material to reflect at a first wavelength;
introducing, using the focused ion beam tool, a second concentration of the doped material to the second active region, the second concentration of the doped material to reflect at a second wavelength, wherein the first concentration and the second concentration are different and the first wavelength and the second wavelength are different;
forming a second DBR on the first and second active regions; and
adding a contact layer on the second DBR.

16. The semiconductor wafer of claim 15, wherein the base material is a compound including gallium arsenide.

17. The semiconductor wafer of claim 15, wherein the doped material is a dilute nitride.

18. The semiconductor wafer of claim 15, wherein the first concentration and the second concentration are less than five percent.

19. The semiconductor wafer of claim 15, wherein:
the semiconductor wafer is configured for use in a laser emitting light at the first wavelength and the second wavelength; and
the laser is a vertical cavity surface emitting laser (VCSEL) or an edge emitting laser (EEL).

20. The semiconductor wafer of claim 15, wherein the doped material is applied to the first active region and the second active region using focused ion beam lithography.
